(19) United States
(12) Patent Application Publication
(10) Pub. No.: US 2005/0193290 A1
(43) Pub. Date: Sep. 1, 2005

(54) Built-in self test method and apparatus for jitter transfer, jitter tolerance, and FIFO data buffer

(76) Inventors: James B. Cho, Plano, TX (US); Bhavesh G. Bhakta, Richardson, TX (US)

Correspondence Address: TEXAS INSTRUMENTS INCORPORATED, P O BOX 655474, M/S 3999, DALLAS, TX, 75265, US

(21) Appl. No.: 10/786,966

(22) Filed: Feb. 25, 2004

(51) Int. Cl. H03B 19/00; G11C 29/00

(52) U.S. Cl. 714/710

(57) ABSTRACT

Testing a transceiver includes providing a sequence of test signals. A serialization clock is generated and jitter is added to the clock in a known and controlled manner. The test signals can then be transmitted using the serialization clock. After the test signals are recovered by the clock and data recovery mechanism, the recovered sequence is compared to the original sequence, to test for jitter tolerance. Preferably, each of these steps is performed on chip. In other aspects, a jitter transfer test and/or a FIFO test can be performed.

### TECHNICAL FIELD

The present invention relates to the field of electronic circuits, and more specifically, to a built-in self test method and apparatus for electronic equipment.

### BACKGROUND

Many electronic components, such as transceivers, receive and/or transmit data at high speed. In particular, a transceiver, such as a serializer/deserializer (SERDES), can receive data in parallel form at an input and provide serial data at an output and vice versa. For example, a system might include two components that process data in parallel and are coupled to one another by a serial link. To transfer information from one component to the other, the first system would convert the parallel data to serial data and place the data on a transmission medium. Upon receipt at the second component, the data would be reconverted from the serial form to parallel form for processing at the second component.

One of the design goals of the transceivers is to ensure that the data received at the second component is an accurate replication of the data sent from the first component. Several factors can adversely impact the efficacy of the transmission process. One factor of interest in the present case is jitter.

Jitter is the amount that a signal is shifted in time relative to a base signal. In an ideal situation, a signal (e.g., an NRZ or Not Return to Zero) would be at a high or a low level at a certain well-defined time. The receiving component could then sample the signal at that time to determine if the transmitted information was logical “1” or a logical “0.” With jitter, however, the signal can arrive either early or late. In order to be accurately sampled, the signal will need to be kept at the desired level (high or low) for a period of time that is long enough to accommodate the jitter. That is, the frequency will need to be lowered.

For a given system to operate properly, a receiver must be designed to handle a certain amount of jitter, regardless of the source of this jitter. Jitter tolerance is a measure of the amount of jitter that can be present in a signal and still be accurately determined by a receiver. To determine jitter tolerance, a test signal is sent to a receiver that is being tested. This test signal includes a known amount of jitter. If the receiver can decipher the signal, then the test has been passed. To determine the tolerance, additional jitter is added until the bit error rate increases beyond an acceptable threshold. Generally, jitter transfer is the amount of jitter a given device adds or takes away when retransmitting a signal that is received, and jitter tolerance is amount of jitter that a device can receive and process without errors.

Testing jitter tolerance and jitter transfer is difficult in many electronic devices, particularly in high-speed communications devices such as SONET transceivers in a production environment. The test requires providing high speed, 612 mega bits per second to 10 giga bits per second or greater, serial data stream with know and adjustable amount of jitter to the device under test (DUT). A means of checking the data received by the DUT for accuracy and a means of measuring the jitter from the DUT in response to the jitter on its input are needed. Thus, the inputs needed for a device to be tested are difficult to generate. Likewise, outputs of the device being tested are difficult to measure. In any event, these tests typically take a long time to perform, e.g., tens of minutes per device on bench equipment. As a result, this type of testing is cost prohibitive for every device being manufactured.

A first in first out (FIFO) circuits are often used in transceivers to facilitate pseudo asynchronous timing between the transmit (TX) data clock external to the chip and the transceiver internal clock. This FIFO near the TX input (TX FIFO) is difficult to test because the external transmit data clock and the transceiver internal clock must be made to phase slip relative to each other until the FIFO experiences an underflow or overflow. The test needs to measure how much phase slip the FIFO can tolerate before experiencing the underflow or overflow.

### SUMMARY OF THE INVENTION

Embodiments of the present invention provide a method and an apparatus to test, among other things, the jitter transfer and jitter tolerance of electronic communication devices. In particular, the preferred embodiment of the present invention relates to a method and an apparatus for providing a built-in self test for jitter transfer and jitter tolerance.

In one aspect, the present invention addresses the demand for high quality transceiver devices. Jitter tolerance and jitter transfer are important specifications to be met for transceivers but due to limitations of the automatic test equipment (ATE) available, these can not be tested for during manufacturing test today. It is unlikely that ATE with timely jitter tolerance and jitter transfer measuring capability will become available during the next few years. Given this deficiency in test capability available through ATE, an alternate means of performing these tests is needed.

In the preferred embodiment, the Built In Self Test method, for measuring jitter tolerance and jitter transfer on transceivers, makes use of transmit (TX) side interpolator to generate desired jitter test patterns. The TX serial data thus generated is looped back to the receive (RX) serial input. PRBS generation/verification mechanism is used to check jitter tolerance and a special up/down counter is used to monitor the movement of the RX clock recovery system and thus measure jitter transfer.

For example, a method of testing a serializer/derserializer includes providing a sequence of test signals (e.g., binary or other multi-level test signals) in parallel form. A serialization clock is generated and jitter is added to the serialization clock in a known and controlled manner. The test signals can then be transmitted using the serialization clock. After the test signals are recovered and deserialized, the deserialized sequence is compared to the original sequence, for example, to test for jitter tolerance. Preferably, each of these steps is performed on chip.

Aspects of the present invention provide a BIST that can be performed on every device shipped and test for jitter tolerance and transfer. This test can be implemented simply by utilizing the PRBS checking mechanism that exists on present day devices. In some embodiments, an up/down counter is used to monitor activity of the receive clock recovery mechanism and test for jitter transfer.

Coincidentally, the BIST mechanism built to test the jitter tolerance and transfer also makes it possible to easily test the TX FIFO.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a block diagram of a transceiver that includes a built-in test mechanism in accordance with one embodiment of the present invention;

FIG. 2 is a block diagram of a transmission clock generator in accordance with one embodiment of the present invention;

FIGS. 3A and 3B show a block diagram of an example of an interpolator;

FIG. 4 is a detailed diagram of a phase interpolator;

FIG. 5 is a block diagram of a transmission interpolator controller in accordance with one embodiment of the present invention;

FIGS. 6A-6C are charts showing outputs of an exemplary interpolation system;

FIG. 7 is a block diagram of a portion of a receive clock generator in accordance with one embodiment of the present invention;

FIG. 8 is a diagram of a FIFO; and

FIG. 9 is a diagram for CONVERTER inside RX Interpolator for receiver based BIST mechanisms.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In one aspect, the present invention provides a method and apparatus to test for jitter tolerance and jitter transfer on a transceiver chip itself. For example, a transmitter side interpolator can be used to generate a desired jitter pattern. Serial data from the transmitter side can be looped back to the receiver's serial input. A pseudo-random binary sequence (PRBS) generation/verification mechanism can then be used to check jitter tolerance. Jitter transfer can be measured using an up/down counter to monitor receiver interpolator activity.

To test for jitter in a SONET system, a high speed (e.g., 622 Mbps to 12 Gbps or higher) serial data stream with known and adjustable amounts of jitter is needed. The test mechanism will then provide a means of checking parallel data from the device under test for accuracy and a means for measuring the jitter from the device under test in response to the jitter on its input. For SONET, these tests should be performed over a large range of modulation frequencies.

A method for building a BIST circuit to measure jitter tolerance and jitter transfer will be shown by going through an example for SONET operating at OC-48 (2,488,320,000 bits per second) rate. This method, however, need not be restricted to SONET. The only restrictions on the types of jitter patterns that can be generated using this method are the user's imagination and the maximum rate at which the TX interpolator implemented to create the jitter can be updated.

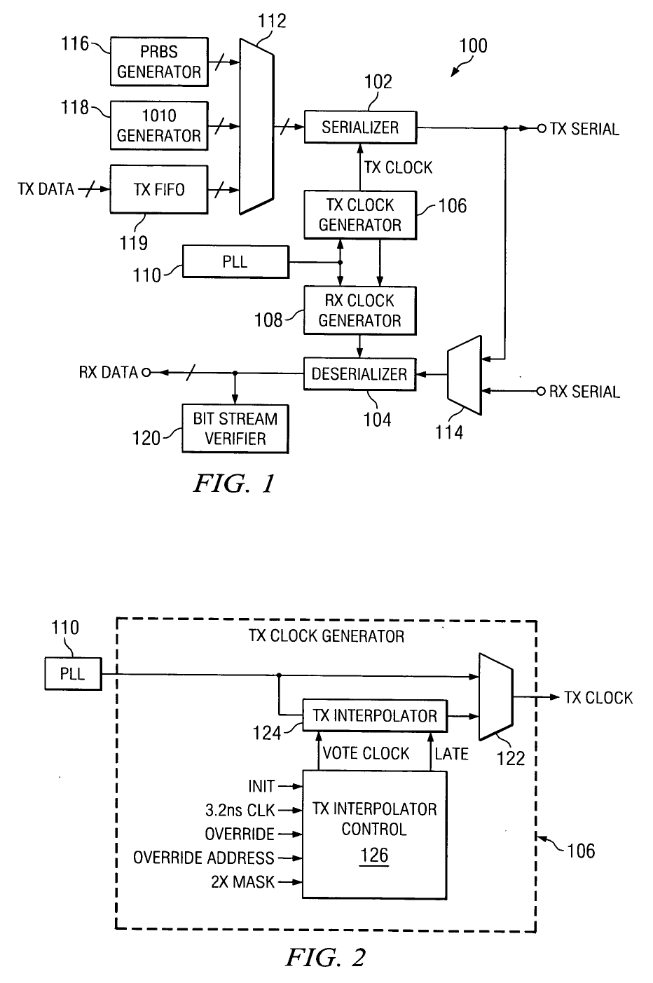

FIG. 1 illustrates a block diagram of a TRANSCEIVER 100 in accordance with a preferred embodiment of the invention. In normal operation, the TRANSCEIVER 100 serves two main functions. Parallel transmission data is received at input (TX DATA) and serialized (in SERIALIZER 102) and serial data is provided at an output (TX SERIAL). In addition, serial transmission data is received at another input (RX SERIAL) and deserialized (at DESERIALIZER 104) and provided to a second output (RX DATA). While drawn with a single line, the input TX DATA and output RX DATA include a number of physical lines (corresponding to the number to bits in a parallel word). In the preferred embodiment, the data is binary data but it is understood that other digital signals, such as multi-level signals like PAM4 and PAM5, can be used.

The SERIALIZER 102 and DESERIALIZER 104 are clocked by clock circuitry that determines the appropriate sample rates to generate the output serial data and to decipher the input serial data. Three blocks in FIG. 1 illustrate the clock circuitry; namely, TX CLOCK GENERATOR 106, RX CLOCK GENERATOR 108, and PLL (phase lock loop) 110. The operation of these blocks during normal operation is known and will not be described herein.

The TRANSCEIVER 100 is also equipped for a number of test modes. For example, rather than receive parallel data from input TX DATA, the TRANSCEIVER 100 can generate test data. Two examples of test data generation circuitry are provided. PRBS (pseudo random binary sequence) GENERATOR 116 generates a sequence of binary data in accordance with a predefined algorithm. 1010 GENERATOR 118 generates a stream of binary values wherein the pattern of binary values is predetermined, such as a stream of alternating zeroes and ones. Other test patterns could be generated, including patterns with non-binary digital signals.

In the preferred embodiment, the test sequence is a built-in self test (BIST). Accordingly, the test data is generated on-chip (i.e., by circuitry located on the same semiconductor substrate as the transceiver circuitry). In other embodiments, the test data could be generated off-chip and provided at input such as TX DATA.

A multiplexer 112 is provided to select a data source to be applied to SERIALIZER 102. In this example, multiplexer 112 couples one of PRBS GENERATOR 116, 1010 GENERATOR 118, or user input TX DATA retimed using the TX FIFO (First In First Out circuit) 119 to the SERIALIZER 102 in accordance to a select signal (not shown). As discussed above, during normal operating modes, the select line is set such that the user data TX DATA is communicated to the SERIALIZER 102, and during testing operations, the select line is set such that a test pattern, either internally or externally generated, is communicated to the SERIALIZER 102.

In this example, DESERIALIZER 104 can receive data from one of two sources as determined by multiplexer 114. During normal operation, serial data RX SERIAL is received at the deserializer 104. During testing, the serial data can be generated off-chip (e.g., received at input RX SERIAL) or generated on-chip (e.g., received from SERIALIZER 102). Thus, both the input node RX SERIAL and the output of SERIALIZER 102 are provided to multiplexer 114, which couples the appropriate signal to the output. As will be discussed in greater detail below, the preferred embodiment uses a technique where parallel test data is generated on-chip, serialized, deserialized and measured to determine accuracy. In particular, this measurement can be performed by BIT STREAM VERIFIER 120.

BIT STREAM VERIFIER 120 is preferably a PRBS verifier. In the preferred embodiment, the PRBS GENERATOR 116 is located inside the transmitter and BIT STREAM VERIFIER 120 is in the receiver. Accordingly, they are separate blocks. Together they are referred to as PRBS generation/verification blocks.

One aspect that differentiates the preferred embodiment from other transceivers is the transceiver's ability to self-test for jitter tolerance and jitter transfer. As will be discussed in greater detail below, this self-test can be implemented by use of a transmit side interpolator driven by a state machine that inserts the desired frequency and magnitude components of the jitter onto the transmit clock. While the particular discussion below pertains to a SONET sine-like frequency modulation, almost any type of jitter can be artificially generated using this method.

A jitter tolerance threshold can be verified by using the PRBS generation and verification mechanism to see if the receive side can tolerate the inserted jitter from the transmit side when the high-speed data is looped back to the receive side. Jitter transfer can be checked by building a mechanism that monitors how much the receive side interpolator moves in response to the jitter from the transmit data that has been looped back. In addition, this scheme provides a technique to test the transmit side FIFO, another component that is difficult to screen during manufacturing test.

Referring once again to FIG. 1, during testing, a binary test pattern is generated and communicated to the SERIALIZER 102. The binary test pattern may be generated by, for example, the PRBS GENERATOR 116, the 1010 GENERATOR 118, or the like. The SERIALIZER 102 serializes the data stream at a rate based on the transmit clock signal TX CLOCK, which has jitter inserted in a controlled and known fashion. This data stream is looped back to the DESERIALIZER 104 where it is returned to parallel form. The BIT STREAM VERIFIER 120 can then compare the bits from DESERIALIZER 104 to the binary test bit patterns to determine the test results. If the data matches, the jitter tolerance test passes.

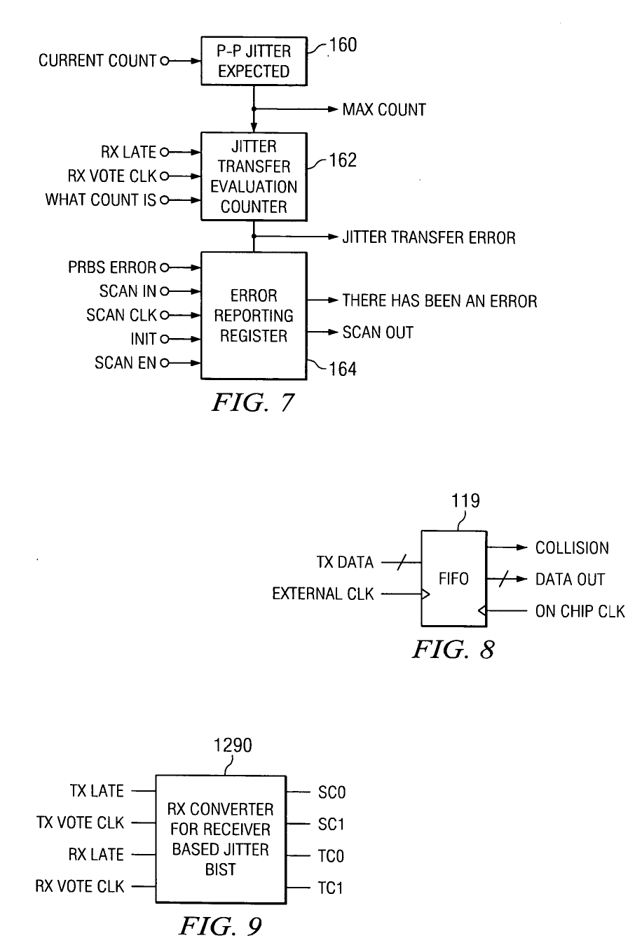

To test for jitter transfer, additional circuitry is preferably added to the receive clock generator 108 to determine if the jitter transfer is too great. This additional circuitry and test method will be described below with respect to FIG. 7.

The TX CLOCK GENERATOR 106 will now be described with respect to FIG. 2. In the preferred embodiment, the TX CLOCK GENERATOR 106 is capable of generating a clock signal modulated at a plurality of frequencies for a plurality of cycles. Most preferably, the clock signal is modulated at eight frequencies: 33.3 KHz, 100 KHz, 158 KHz, 251 KHz, 398 KHz, 631 KHz, 1 MHz, and 2.5 MHz. The clock signal is preferably modulated at each frequency for 16 cycles, the number of cycles determined reasonable to accurately test each frequency without taking too much time. Other frequencies and counts may be used. In an alternative mode, a specific frequency may be selected.

In normal operation, the transmit clock TX CLOCK is generated on-chip by the PLL (phase lock loop) 110. This clock signal is transferred through the TX CLOCK GENERATOR 106 through multiplexer 122. During test operation, the PLL clock is shifted through TX INTERPOLATOR 124 that inserts the test jitter. During this test mode, the multiplexer 122 provides the output of the TX INTERPOLATOR as the transmit clock TX CLOCK.

The TX INTERPOLATOR 124 is used to modulate the clock signal from PLL 110, e.g., shift the PLL clock phase a selected amount either forward or back in time. During this test, the PLL must have a local feedback divider path to make sure the signals being fed to the interpolator are phase locked to the reference clock. This will ensure that the TX CLOCK derived from the interpolator is modulated relative to the reference clock.

The TX INTERPOLATOR CONTROL 126 determines the amount of the shift. In the illustrated embodiment, two control signals are provided. One signal (VOTE CLK) increments the interpolator by a single step while the other (LATE) determines the direction of the increment. In other interpolation circuits, other control signals can be used.

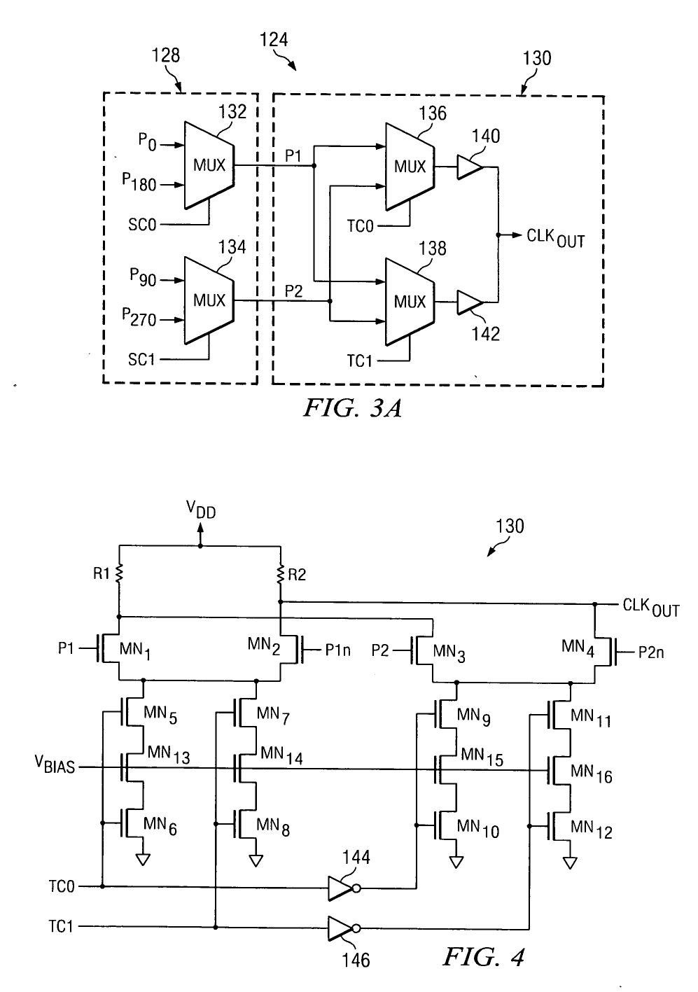

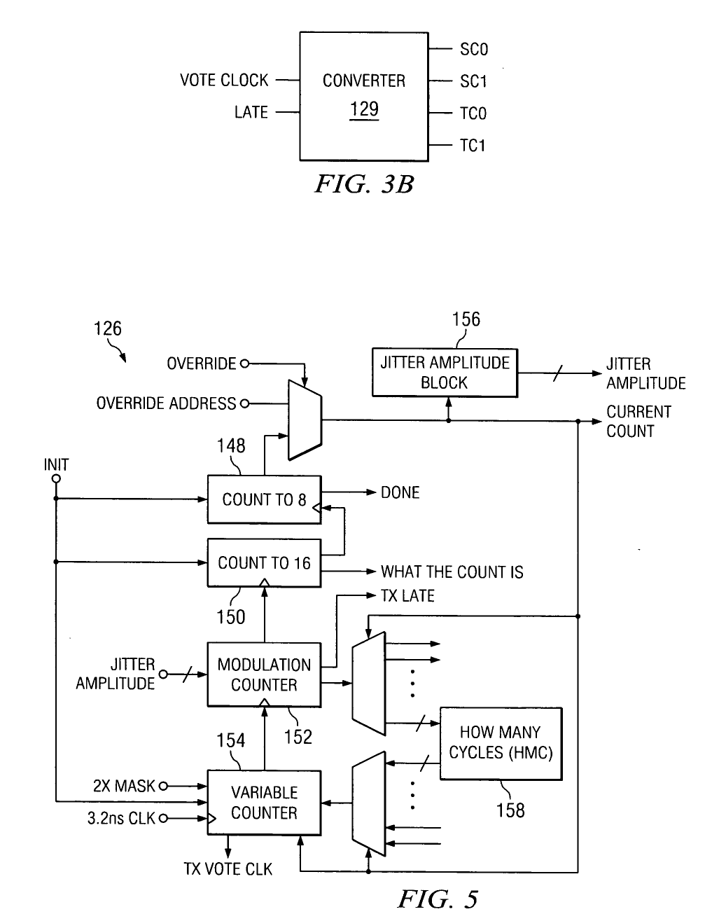

A specific implementation of TX INTERPOLATOR 124 is provided in FIG. 3 (which includes FIGS. 3A and 3B) and FIG. 4. FIG. 3 depicts an illustrative embodiment of the TX INTERPOLATOR 124 while FIG. 4 depicts a representative implementation of the PHASE INTERPOLATOR 130 of FIG. 3. Description of these circuits is also provided in co-pending application Ser. No. 10/662,596 filed Sep. 15, 2003 (TI-34685), which is incorporated herein by reference.

As shown in FIG. 3, the TX INTERPOLATOR 124 comprises a CONTROLLER 129, a PHASE SELECTOR 128 and a PHASE INTERPOLATOR 130. The CONTROLLER 129 is a state machine that converts direction (LATE) and step (VOTE CLK) information into control signals SC0, SC1, TC0, and TC1, which directly control the muxes in the PHASE SELECTOR 128 and PHASE INTERPOLATOR 130. The PHASE SELECTOR 128 includes a plurality of multiplexors (MUXs) 132-134, which are configured to select two of the four phases P₀, P₉₀, P₁₈₀, and P₂₇₀ (which are from the PLL 110 in FIG. 2) based on the logical values of the Sector Codes SC0, SC1 applied thereto. The phase interpolator 130 includes a plurality of MUXs 136-138 and associated output buffers 140-142. The MUXs 132-134 provide outputs P1-P2, respectively, to the MUXs 136-138, each of which is configured to select between the outputs P1-P2 based on the logical values of the Thermometer Codes TC0, TC1 applied thereto. The MUXs 136-138 provide their respective outputs to the buffers 140-142, the outputs of which are combined to generate the output clock signal CLK_{OUT}.

For example, when SC0=SC1=0, the MUX 132 provides the phase P₀ as its output P1 and the MUX 134 provides the phase P₉₀ as its output P2. It is noted that in the event SC0=SC1=1, the MUX 132 alternatively provides the phase P₁₈₀ as its output P1 and the MUX 134 alternatively provides the phase P₂₇₀ as its output P2. When the PHASE SELECTOR 128 provides the phases P₀ and P₉₀ to the PHASE INTERPOLATOR 130; the PHASE INTERPOLATOR 130 operates in the 1^{st} sector. For clarity of discussion, it is assumed that the MUXs 132-138 and the output buffers 140-142 have zero delays associated therewith.

As a result, in the event TC0=TC1=0, the MUXs 136-138 each provide the output P1, i.e., the phase P₀, at their respective outputs, which are provided via the output buffers 140-142 as the output clock CLK_{OUT}. In the event TC0=0 and TC1=1, the MUXs 136-138 provide the outputs P1 (i.e., the phase P₀) and P2 (i.e., the phase P₉₀) at their respective outputs, which are combined via the output buffers 140-142 to generate a phase half way between the phases P₀ and P₉₀ (i.e., a phase P₄₅) as the output clock CLK_{OUT}. In the event TC0=TC1=1, the MUXs 136-138 each provide the output P2, i.e., the phase P₉₀, at their respective outputs, which are provided via the output buffers 140-142 as the output clock CLK_{OUT}.

FIG. 4 depicts a representative implementation of the PHASE INTERPOLATOR 130. In the illustrated embodiment, the PHASE INTERPOLATOR 130 is a differential interpolator comprising a plurality of switching elements including n-channel transistors MN₁-MN₁₆, a pair of pull-up resistors R1-R2, and inverters 144-146. The Thermometer Codes TC0-TC1 are applied to the gates of the transistors MN5-MN6 and MN7-MN8, respectively, and inverted forms of the Codes TC0-TC1 are applied to the gates of the transistors MN9-MN10 and MN11-MN12, respectively. Further, the inputs P1-P2 (see also FIG. 3) are applied to the gates of the transistors MN1 and MN3, and inverted forms of the inputs P1-P2 (i.e., P1n-P2n) are applied to the gates of the transistors MN2 and MN4, respectively. Moreover, a voltage V_{BIAS} is applied to the gates of the transistors MN13-MN16 for suitably biasing the differential stages. In the event SC0=SC1=0 (i.e., P1=P₀ and P2=P₉₀) and TC0=1, TC1=0, the output clock CLK_{OUT} is equal to P₄₅, which is half way between the phases 0° and 90°.

Returning to FIG. 2, the TX INTERPOLATOR 124 is controlled by TX INTERPOLATOR CONTROL 126. TX INTERPOLATOR CONTROL 126 derives the signals VOTE CLK and LATE that determine the phase output as discussed above. The inputs to the TX INTERPOLATOR CONTROL 126 are listed here:
2× MASK: This signal controls whether the interpolator control will cause the interpolator to generate a 1× or 2× SONET jitter tolerance mask;
OVERRIDE: This signal indicates whether the test should be run automatically or manually (i.e., in override mode);
OVERRIDE ADDRESS: This signal provides the address of the test frequency in override mode;
3.2 NS CLK: This clock is derived by dividing the transmit clock TX CLOCK; and
INIT: The rising edge of INIT starts everything. The TX INTERPOLATOR CONTROL 126 is disabled when INIT is low.

As noted above, the signal 2× MASK determines whether the TX INTERPOLATOR CONTROL 126 generates a 1× or a 2× jitter tolerance mask. The use of a 2× mask allows for a guardband during testing. If a mask is utilized that requires a signal to be within a given threshold and the result is close to that threshold, the result might be inaccurate due to inaccuracies in the testing. Utilizing a 2× mask doubles the threshold thereby providing an assurance that the part that passes, even if measured without total accuracy, will meet the specification.

In automatic mode, the clock is modulated at a number of frequencies, e.g., 33.3 kHz, 100 kHz, 158 kHz, 251 kHz, 398 kHz, 631 kHz, 1 MHz, and 2.5 MHz for a SONET OC-48 system. The test will start with the lowest modulation frequency and go through 16 cycles before moving on to the next. In override mode as indicated by the OVERRIDE signal, the user can choose which one of these frequencies to modulate at by properly setting the signal OVERRIDE ADDRESS. For example, in the preferred embodiment the clock signal can be modulated at eight different frequencies. If the OVERRIDE signal is applied, the frequency corresponding to the OVERRIDE ADDRESS will be used for the test.

Table 1 provides a very specific example where eight modulation frequencies will be used to test an OC-48 rate system. As discussed above, the BIST has an automatic mode, where the clock would be modulated at these frequencies. In OVERRIDE mode, one can choose which one of these frequencies to modulate at by properly setting the OVERRIDE ADDRESS.

TABLE 1

| Modulation Frequency | 1X Jitter Amplitude | 2X Jitter Amplitude |
|---|---|---|
| (kHz) | (UI) | (UI) |
| 33.3 | 1.5 | 3.0 |
| 100 | 1.5 | 3.0 |
| 158 | 0.94937 | 1.89873 |
| 251 | 0.59761 | 1.19522 |
| 398 | 0.37688 | 0.75377 |
| 631 | 0.23772 | 0.47544 |
| 1000 | 0.15 | 0.3 |
| 2000 | 0.15 | 0.3 |

FIG. 5 provides a detailed illustration of how the TX INTERPOLATOR CONTROL 126 can be implemented. The parts and how they function are described in the following paragraphs. As will be described, the test will start with the lowest modulation frequency and modulate the high-speed clock for 16 cycles before moving on to the next frequency. At each modulation frequency, look up tables indicate what the jitter amplitude should be and how the interpolator should be driven to create the desired jitter pattern.

When the initialization signal INIT is low, the COUNT TO 8 block 148, the COUNT TO 16 block 150, the MODULATION COUNTER 152, and the VARIABLE COUNTER 154 are all disabled. When the signal INIT is high, the output of COUNT TO 8 block 148 (CURRENT COUNT) determines which frequency will be used to modulate the transmission clock. The signal CURRENT COUNT determines what the frequency and amplitude of the jitter will be.

The JITTER AMPLITUDE BLOCK 156 is a combinatorial circuit whose output indicates what the jitter amplitude should be. Note that JITTER AMPLITUDE is input to the MODULATION COUNTER 152. The JITTER AMPLITUDE signal represents how many interpolator steps need to be taken to achieve the desired amplitude. For example, for 100 kHz case, where it is desired that the amplitude be 1.5 UI, if the interpolator needs to take 100 steps to move 1 UI, JITTER AMPLITUDE will be set to 150. The state of signal CURRENT COUNT also determines which of the seven HMC (How Many Cycles) blocks 158 gets used.

The COUNT TO 8 block 148 gets clocked and updated by the COUNT TO 16 block 150. The COUNT TO 16 block 150 ensures that the modulation is done for 16 cycles (or whatever other count is selected) at each frequency before the test mechanism moves on to the next modulation frequency. The COUNT TO 16 block 150 gets clocked and updated by the MODULATION COUNTER 152. Note that the MODULATION COUNTER 152 generates the TX LATE signal to tell the TX INTERPOLATOR 124 which way to move.

The MODULATION COUNTER 152 counts from 0 to the JITTER AMPLITUDE value and back. The output of the MODULATION COUNTER 152 goes to one of seven HMC blocks 158 chosen by the state of CURRENT COUNT. The HMC 158 are combinatorial circuits that indicate how many 3.2 ns cycles there should be between interpolator updates based on the desired modulation frequency and the state of the modulation counter. The MODULATION COUNTER 152 gets clocked and updated by the VARIABLE COUNTER 154.

The VARIABLE COUNTER 154 uses the output of the HMC blocks 158 to wait the appropriate amount of time before sending out a TX VOTE CLK pulse. At the same time, it clocks the MODULATION COUNTER 152 to get the next value of how long it should wait before sending out the next clock pulse. If the 2× MASK signal is low, it tells the VARIABLE COUNTER 154 to send out only every other TX VOTE CLK pulse. The entire system outside of the VARIABLE COUNTER 154 is geared for generating a 2× Mask. If a 1× Mask is needed, the TX VOTE CLK will pulse only half as much to get the 1× Mask.

Since the amplitude needed in the 33.3 kHz is identical to that of 100 kHz (see Table 1), the same HMC block 258 used for the 100 kHz case is used for the 33.3 kHz case. In the 33.3 kHz case, the 3.2 ns clock gets divided by 3 so that the resulting modulation frequency becomes 33.3 kHz instead of 100 kHz. This explains why there are only seven HMC blocks 258 while there are eight frequencies to modulate at. The signal CURRENT COUNT is used by the VARIABLE COUNTER 154 to determine when the system is in the 33.3 kHz mode.

Once the TX INTERPOLATOR CONTROL has gone through all the frequencies, it will set the DONE flag.

The HMC block 258 is particularly useful in allowing this scheme to succeed and therefore will be discussed in some greater detail here. A PERL script was developed that will create a list of intervals to wait based on 1) how many interpolator steps are needed to traverse one unit interval, 2) the scale of the jitter mask desired (e.g., 1×, 2×, etc.), and 3) the minimum interval (min int) at which the TX interpolator can be updated (This was 3.2 ns in the scheme shown on FIG. 5).

Before describing in detail how the algorithm works, some clarification will be provided on the use of the term unit interval or UI. There term “UI” is used here in two different contexts. One UI in terms of time is equal to one bit time (approximately 400 pico seconds in OC-48 mode). There is also the UI as it relates to the amplitude of jitter. This second UI corresponds to the number steps and direction in which the interpolator needs to be manipulated to move the phase of the interpolator output 1 UI relative to the PLL output.

The algorithm that is used has the following features:
(1) Based on the modulation frequency of interest, determine how many unit intervals (or bit times) can be spent to modulate 1 cycle (cycle_interval).
(2) Based on the jitter mask scale and modulation frequency, determine what the jitter amplitude (in UI) should be (amplitude).
(3) Half of “amplitude” represents how much the interpolator must move in quarter of “cycle_interval” (height).
(4) Number of interpolator steps needed to move “height” is “height” (in UIs) multiplied by how many steps are needed to traverse 1 UI (steps in a quarter).
(5) Scale the number of “steps in a quarter” into 1.1/“steps in a quarter” represent the “scaled step increment.” The goal here is to map the amount of UIs that need to be traversed in ¼ cycle, which has been translated to number of interpolator steps that need to be taken, into a sine value.

The algorithm itself is provided here:

From I=1 to I=“steps in a quarter” incrementing by 1 do the following
Get “sine value”=I*“scaled step increment”
Get the “angle” that corresponds with the “sine value” by doing arcsine of the “sine value.”
   (This represents what the phase or the angle value should be after the Ith step. In PERL script this value is returned in radians.)
Find out how many bit times should have been spent to get to this angle.
   ((angle/(2*3.14159))*″cycle_interval″)
What does the above number of bit time correspond to if we round to and convert to the nearest
   “min int”
Subtract the present number of “min int” from that of I-1 evaluation. Lets call this “wait period”
   Print value of I and “wait period”

Get to next value of I

End of Algorithm

The algorithm specifies how many minimum intervals (“min int”) should be spent at each step as the interpolator gets updated so that the resulting signal coming out of the interpolator simulates a signal modulated at the given frequency with the given JITTER AMPLITUDE. The algorithm gives the values for only ¼ of the cycle but that is all that is needed. To create a complete cycle using the blocks in FIG. 5, TX LATE starts low; the ¼ cycle is gone through with the MODULATION COUNTER 152 counting from 0 to the JITTER AMPLITUDE. The signal TX LATE is set high and the same steps are gone through but now with the MODULATION COUNTER 152 counting backwards. Once the count reaches 0, the signal TX LATE is kept high and the counter counts to JITTER AMPLITUDE. The signal TX LATE can then be changed to low and count backward to 0 again and repeat. Note that every time the count reaches JITTER AMPLITUDE, the value of TX LATE toggles.

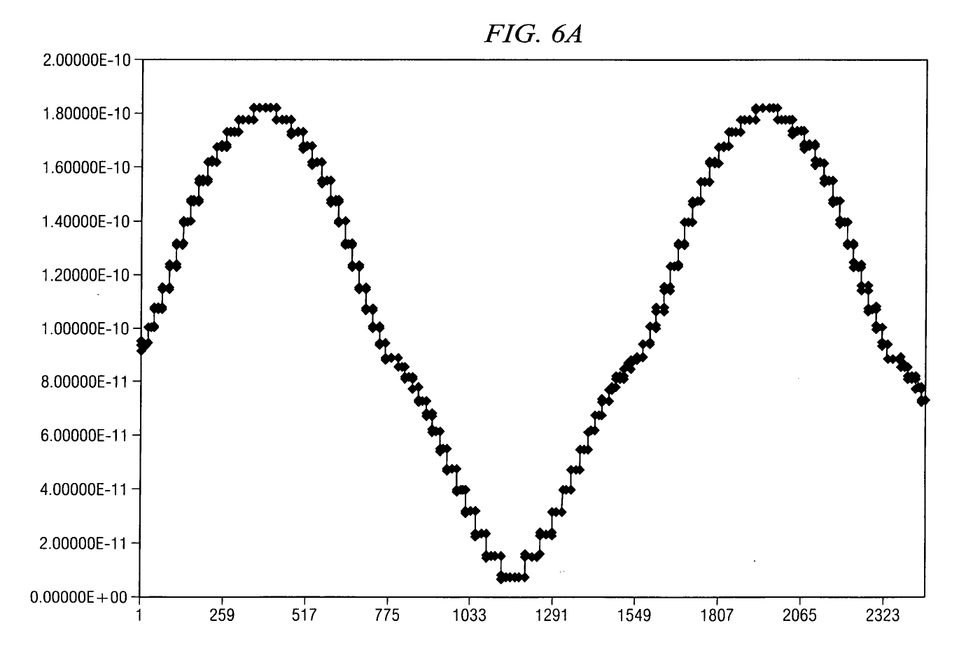

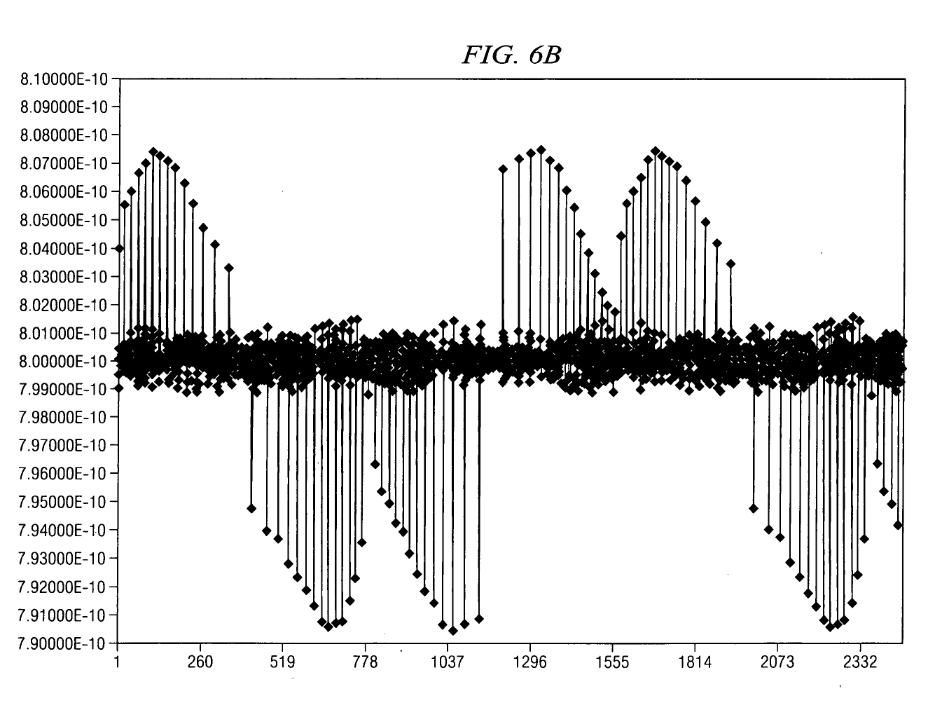

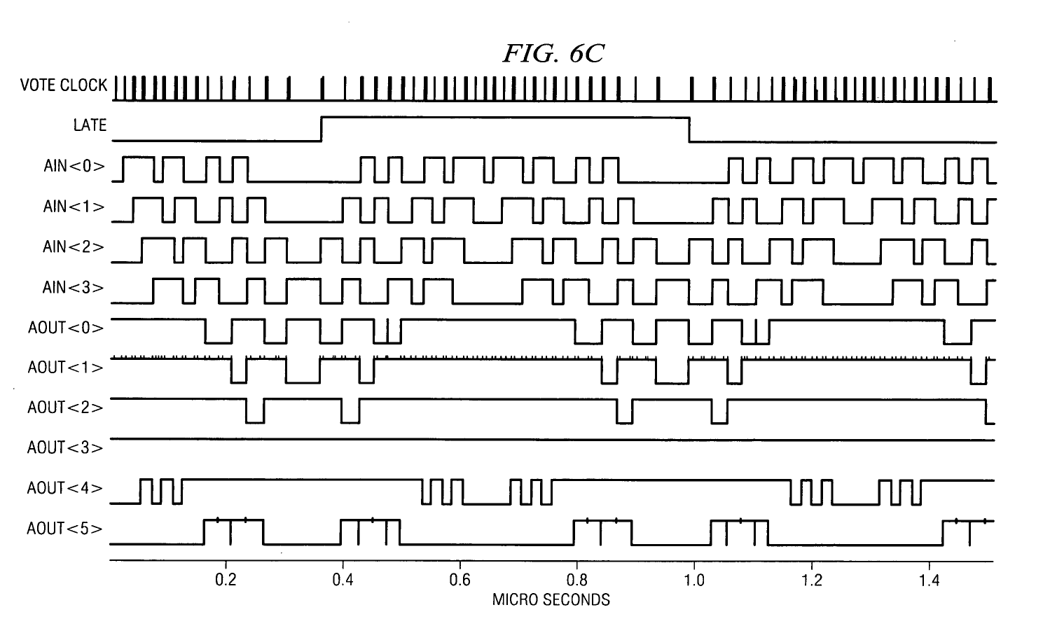

FIGS. 6A-6C provide charts showing the outputs of the interpolator for a SONET example. In particular, FIG. 6A shows the interpolator output phase. FIG. 6B shows the interpolator output cycles and FIG. 6C shows the interpolator control output. These charts show the results and signals described above. In FIG. 6C, AIN<x> represent inputs to the HMC 158 and AOUT<x> represent outputs of HMC 158. Note that VOTE CLK causes AIN<x> to be updated and the change in AIN<X> causes AOUT<x> to be updated after a small delay.

The mechanism just described can be utilized in a number of tests. Three of these tests will be described briefly from the standpoint of the user. To perform the jitter tolerance test, the device is put into PRBS test mode and the TX INTERPOLATOR CONTROL 126 is placed in 1× or 2× mask mode. The PRBS TX serial data is looped back to the DESERIALIZER 104 and recovered data compared by the BIT STREAM VERIFIER 120. The test result can be seen on the PRBS pass pin, which is the output of the BIT STREAM VERIFIER 120. If PRBS passes, it shows that the receiver is capable of tolerating the 1× or 2× SONET mask.

A more detailed view of a FIFO 119 is shown on FIG. 8 to better illustrate the FIFO test. EXTERNAL CLOCK is used to latch the FIFO input data (TX DATA). The ON CHIP CLOCK (a divided version of the TX CLOCK for the embodiment shown in FIG. 1) is used to bring out DATA OUT. The job of the FIFO is to resolve the phase difference between the EXTERNAL CLOCK and the ON CHIP CLOCK. FIFO contains 2 registers each clocked by the 2 clocks and a control mechanism that ensures that versions of TX DATA in the first register get safely transferred to the second register. If the phase between the 2 clocks slip so much that registers run out of latches, an overflow or underflow error occurs and the COLLISION signal would pulse. The TX FIFO test comes almost for free because the user can put in a PRBS pattern from the parallel inputs TX DATA of the TRANSCEIVER 100. The modulation is turned on (introducing phase slips onto ON CHIP CLOCK) and the device is checked by reference to the PRBS pass and FIFO collision pins (in FIG. 1, PRBS pass signal would be output from BIT STREAM VERIFIER 120. The FIFO collision signal would be from the TX FIFO 119). The modulating action of the TX INTERPOLATOR 124 causes the ON CHIP CLOCK to slip in phase relative to the EXTERNAL CLOCK. This is precisely what is needed to test the TX FIFO and is difficult to achieve during manufacturing test using an automatic test equipment. The overhead needed is the ability to turn on the BIT STREAM VERIFIER 120 while bypassing the PRBS GENERATOR 116.

The jitter transfer test is not as simple as the tolerance test and some special circuits need to be added to the RX CLOCK GENERATOR 108 to measure the transfer. These are shown in FIG. 7. Note what is not shown in FIG. 7 are the RX Interpolator control circuit and the RX Interpolator. The RX Interpolator would be identical to the TX Interpolator. The RX Interpolator control circuit monitors the transitioning edges of the RX SERIAL data and generates the RX LATE and RX VOTE CLK signals. The RX LATE and RX VOTE CLK adjust the output of the RX Interpolator so that the RX Clock (which is RX side's equivalent signal to the TX CLK of FIG. 2 and is derived from the output of the RX Interpolator) transitions in the middle of the RX SERIAL Data. RX Clock is the clock recovered from the serial data stream.

A brief description of the input signals for the transfer measuring mechanism is provided first:
CURRENT COUNT is routed from the COUNT TO 8 block 148 in the TX INTERPOLATOR CONTROL 126;
RX LATE is the LATE signal for the RX Interpolator;
RX VOTE CLK is the VOTE CLK signal for the RX Interpolator;
WHAT THE COUNT IS is from the COUNT TO 16 block 150 in the TX INTERPOLATOR CONTROL 126 (FIG. 5);
PRBS ERROR is from the PRBS Verification block and/or the 1010 Verification block (which are within the BIT STREAM VERIFIER 120 of FIG. 1);
SCAN IN, SCAN OUT, SCAN CLK, and SCAN EN are used to scan out the contents of the ERROR REPORTING REGISTER 164.

Turning now to the circuit blocks of FIG. 7, the P-P (Peak-to-Peak) JITTER EXPECTED block 160 creates a value based on CURRENT COUNT of how much the receive interpolator could move without violating the SONET transfer mask. The JITTER TRANSFER EVALUATION COUNTER 162 increments when RX LATE is high and decrements when RX LATE is low. In any event, this block will not decrement below 0. That is, if RX LATE is low and RX VOTE CLK is pulsing, the count remains 0 and will not decrement lower.

The JITTER TRANSFER EVALUATION COUNTER 162 remains reset if WHAT THE COUNT IS is below 4 or above 14. Thus when a new modulation frequency begins, it is in a reset state. Once there have been three modulating cycles, it starts to increment and decrement according to the activities of RX LATE and RX VOTE CLK. If the count reaches the MAX COUNT value, it generates a JITTER TRANSFER ERROR pulse. This signals the ERROR REPORTING REGISTER 164 to latch the value of CURRENT COUNT so that it can be determined at which modulation frequency the transfer error occurred.

The ERROR REPORTING REGISTER 164 also reacts to the PRBS ERROR pulse so that it can also be determined at which modulating frequency a jitter tolerance error has occurred. The first time any error gets detected after INIT had gone high, the THERE HAS BEEN AN ERROR bit gets set. Once WHAT THE COUNT IS reaches 15, the JITTER TRANSFER EVALUATION COUNTER 162 gets reset. As CURRENT COUNT changes, new MAX COUNT gets set up and evaluation starts for the new modulation frequency once WHAT THE COUNT IS reaches 4.

In the above description, the mechanisms to create and add jitter were on the transmit side. In an alternative embodiment, jitter adding mechanisms described herein can be utilized on the receiver side. After all, jitter tolerance and jitter transfer are tests for the receiver. For example, this embodiment can be accomplished by having the TX INTERPOLATOR CONTROL 126 (see e.g., FIG. 5) drive the RX INTERPOLATOR (e.g., within RX CLOCK GENERATOR 108 in FIG. 1). The CONVERTER (see e.g., FIG. 3A, 129) inside the Rx Interpolator (1290 of FIG.9) would be made capable of accepting VOTE CLOCK and LATE from both the TX INTERPOLATOR CONTROL 126 (e.g., the thing that generates the jitter) and the RX INTERPOLATOR CONTROL circuit (the thing that is attempting to recover the clock from the serial data). Under the system just described, a RX SERIAL data that contains negligible jitter relative to the reference clocks could be presented to the receiver circuit. The TX INTERPOLATOR CONTROL 126 will attempt to disrupt the mechanism (the RX Interpolator and the RX Interpolator Control) that is attempting to recover the clock from the serial data stream. The net effect would be that the recovery mechanism would have to do the same work as it would have had to do when it was presented with RX SERIAL data that had jitter put on it. If PRBS tests pass under these circumstances and the reaction of RX LATE and RX VOTE CLK is appropriate given the amount of jitter the TX INTERPOLATOR CONTROL 126 attempted to inject, it can be concluded that the receiver passes jitter tolerance and jitter transfer.

Although the present invention and its advantages have been described in detail, it should be understood that various changes, substitutions and alterations can be made herein without departing from the spirit and scope of the invention as defined by the appended claims.

1. A method of testing a serial transceiver chip for jitter tolerance, the transceiver including at least one transmitter and at least one receiver, the method comprising:
generating a serialization clock;
adding one or more known and controlled amount of jitter to the serialization clock;
transmitting a known sequence of test signals using the serialization clock with the added jitter;
causing a clock and data recovery mechanism in a receiver to recover the test signals; and
comparing the recovered test signals with said known sequence of test signals thereby testing the ability of the clock and data recovery mechanism to tolerate the jitter that was added;
wherein the steps of generating a serialization clock, adding one or more known and controlled amount of jitter to the serialization clock, transmitting a known sequence of test signals using the serialization clock with the added jitter, and causing a clock and data recovery mechanism in the receiver to recover the test signals with jitter are all performed inside the serial transceiver chip.

2. The method of claim 1 wherein the known sequence of test signals is created by a PRBS (Pseudo Random Binary Sequence) generation mechanism and wherein comparing the recovered test signals is done by use of the PRBS verification mechanism.

3. The method of claim 2 wherein creating the known sequence of test signals and comparing the recovered sequence of test signals is performed inside the serial transceiver chip.

4. The method of claim 1 wherein the known sequence of test signals is created inside the serial transceiver chip and wherein comparing the recovered sequence of test signals is also performed inside the serial transceiver chip.

5. The method of claim 1 wherein adding one or more known and controlled amount of jitter is performed by use of an interpolator and an interpolator control mechanism programmed to create the known and controlled amount of jitter.

6. The method of claim 5 wherein the known sequence of test signals is created by a PRBS (Pseudo Random Binary Sequence) generation mechanism and wherein comparing the recovered test signals is done by use of the PRBS verification mechanism.

7. The method of claim 6 wherein creating the known sequence of test signals and comparing the recovered sequence of test signals is performed inside the serial transceiver chip.

8. The method of claim 5 wherein the known sequence of test signals is created inside the serial transceiver chip and wherein comparing the recovered sequence of test signals is also performed inside the serial transceiver chip.

9. A method of testing a serial receiver for jitter tolerance, the serial receiver being fully contained on a single semiconductor substrate, the method comprising:
generating a known sequence of test signals containing negligible jitter relative to a local reference clock;
causing a clock and data recovery mechanism in the serial receiver to recover the test signals;
adding one or more known and controlled amount of jitter into the clock recovery mechanism to force the clock recovery mechanism to compensate for the added jitter; and
comparing the recovered test signals with said known sequence of test signals thereby testing the ability of the clock and data recovery mechanism to tolerate the jitter that was added;
wherein the steps of causing a clock and data recovery mechanism in the receiver to recover the test signals, and adding the known and controlled amount of jitter to the clock recovery mechanism are all performed inside the serial receiver.

10. The method of claim 9 wherein the known sequence of test signals is created by a PRBS (Pseudo Random Binary Sequence) generation mechanism and wherein comparing the recovered test signals is done by use of a PRBS verification mechanism.

11. The method of claim 10 wherein comparing the recovered sequence of test signals is performed inside the serial receiver.

12. The method of claim 9 wherein comparing the recovered sequence of test signals is performed inside the serial receiver.

13. The method of claim 9 wherein adding one or more known and controlled amount of jitter is performed by use of an interpolator control mechanism programmed to create the known and controlled amount of jitter.

14. The method of claim 13 wherein the known sequence of test signals is created by a PRBS (Pseudo Random Binary Sequence) generation mechanism and wherein comparing the recovered test signals is done by use of a PRBS verification mechanism.

15. The method of claim 14 wherein comparing the recovered sequence of test signals is performed inside the serial receiver.

16. The method of claim 13 wherein comparing the recovered sequence of test signals is performed inside the serial receiver.

17. A method of testing a serial transceiver for jitter transfer, the serial transceiver including at least one transmitter and at least one receiver, the serial transceiver being fully contained on a single semiconductor substrate, the method comprising:
generating a serialization clock;
adding one or more known and controlled amounts of jitter to the serialization clock;
transmitting a sequence of test signals using the serialization clock with the added jitter;
causing a clock and data recovery mechanism in a receiver to recover a clock signal from the transmitted sequence of test signals;
monitoring and measuring an amount of jitter present in the recovered clock signal; and
comparing jitter present in the recovered clock with jitter added to the serialization clock thereby testing the jitter transfer characteristic of the transceiver;
wherein the steps of generating a serialization clock, adding jitter to the serialization clock, transmitting a sequence of test signals, monitoring and measuring an amount of jitter in the recovered clock signal, and comparing jitter present in the recovered clock with jitter added to the serialization clock are all performed inside the serial transceiver.

18. The method of claim 17 wherein adding one or more known and controlled amounts of jitter is performed by use of an interpolator and an interpolator control mechanism programmed to create the known and controlled amounts of jitter.

19. The method of claim 17 wherein monitoring and measuring the amount of jitter present in the recovered clock signal is performed by use of an up/down counter that is responsive to direction and step control signals for an interpolator used for clock recovery, and wherein comparing the jitter present in the recovered clock signal is performed by use of a programmable comparator set to issue a warning if a maximum count achieved by an up/down counter exceeds the maximum allowed to pass the transfer test.

20. The method of claim 17 wherein:
adding one or more known and controlled amounts of jitter is performed by use of an interpolator and an interpolator control mechanism programmed to create the known and controlled amounts of jitter;
monitoring and measuring the amount of jitter present in the recovered clock signal is performed by use of an up/down counter that is responsive to direction and step control signals for the interpolator used for clock recovery;
comparing jitter present in the recovered clock with jitter added to the serialization clock is performed by use of a programmable comparator that is set to issue a warning if a maximum count achieved by an up/down counter exceeds a maximum allowed to pass a transfer test.

21. The method of claim 20 wherein the sequence of test signals are generated on the single semiconductor substrate that also contains the transceiver.

22. The method of claim 17 wherein the sequence of test signals are generated on the single semiconductor substrate that also contains the transceiver.

23. A method of testing a serial receiver for jitter transfer, the serial receiver being fully contained on a single semiconductor substrate, the method comprising:
generating a sequence of test signals containing negligible jitter relative to a local reference clock;
causing a clock recovery mechanism in the serial receiver to recover a clock signal from the sequence of test signals, the clock recovery mechanism contained on the single semiconductor substrate;
adding one or more known and controlled amounts of jitter into the clock recovery mechanism to force the clock recovery mechanism to compensate for added jitter;
monitoring and measuring an amount of activity in the clock recovery mechanism; and
comparing the amount of activity in the clock recovery mechanism with an expected amount of activity that is based on the jitter added thereby testing a jitter transfer characteristic of the receiver;
wherein the steps of adding one or more known and controlled amounts of jitter into the clock recovery mechanism, monitoring and measuring an amount of activity in the clock recovery mechanism, and comparing the amount of activity in the clock recovery mechanism with an expected amount of activity are all performed inside the serial receiver.

24. The method of claim 23 wherein adding one or more known and controlled amounts of jitter is performed by use of an interpolator control mechanism that is programmed to create the known and controlled amounts of jitter.

25. The method of claim 24 wherein monitoring and measuring the amount of activity in the clock recovery mechanism is performed by use of an up/down counter that is responsive to direction and step control signals for an interpolator used for clock recovery, and wherein comparing the amount of activity in the clock recovery mechanism with the expected amount of activity is performed by use of a programmable comparator set to issue a warning if a maximum count achieved by an up/down counter exceeds the maximum allowed to pass the transfer test.

26. The method of claim 23 wherein monitoring and measuring the amount of activity in the clock recovery mechanism is performed by use of an up/down counter that is responsive to direction and step control signals for an interpolator used for clock recovery, and wherein comparing the amount of activity in the clock recovery mechanism with the expected amount of activity is performed by use of a programmable comparator set to issue a warning if a maximum count achieved by an up/down counter exceeds the maximum allowed to pass the transfer test.

27. The method of claim 26 wherein the sequence of test signals are generated on the single semiconductor substrate that also contains the receiver.

28. The method of claim 23 wherein the sequence of test signals are generated on the single semiconductor substrate that also contains the receiver.

29. A method of testing a FIFO (First In First Out) circuit on a single semiconductor substrate, the method comprising:
generating an on-chip clock at the same frequency as a reference clock;
incrementally adding a known and controlled amount of phase shifts to the on-chip clock signal;
using the reference clock and the phase-shifted on-chip clock to drive the FIFO circuit; and
measuring an amount of phase-shift that can be added to the on-chip clock signal before the FIFO experiences overflow and/or underflow errors;
wherein the steps of generating an on-chip clock, incrementally adding a known and controlled amount of phase shifts, using the reference clock and the phase-shifted on-chip clock to drive the FIFO circuit, and measuring an amount of phase-shift are all performed on the single semiconductor substrate.

30. The method of claim 29 and further comprising:
providing a PRBS pattern to be used as input data for the FIFO; and
checking output data from the FIFO with a PRBS verifier, the PRBS verifier being disposed on the single semiconductor substrate.

31. The method of claim 30 wherein the PRBS pattern is provided by an on-chip PRBS generator clocked by the reference clock signal.

32. The method of claim 29 wherein incrementally adding a known and controlled amount of phase shifts is performed by use of an interpolator and an interpolator control mechanism programmed to create desired phase shifts.

33. The method of claim 32 and further comprising:
providing a PRBS pattern to be used as input data for the FIFO; and
checking output data from the FIFO with a PRBS verifier, the PRBS verifier being disposed on the single semiconductor substrate.

34. The method of claim 33 wherein the PRBS pattern is provided by an on-chip PRBS generator clocked by the reference clock signal.

35. A built-in self-test (BIST) apparatus for jitter tolerance for use on a serial transceiver, the serial transceiver including one or more transmitters and one or more receivers disposed on a single semiconductor substrate, the BIST apparatus comprising:
a serialization clock generator for generating a serialization clock;
a mechanism for adding one or more known and controlled amounts of jitter to the serialization clock;
a transmitter that uses the serialization clock with added jitter to transmit a known sequence of test signals;
a clock and data recovery mechanism in a receiver to recover the test signals; and
a bit stream verification mechanism used to verify that the recovered test signals match the known sequence of test signals thereby determining whether the clock and data recovery mechanism can tolerate the jitter that was added;
wherein the serialization clock generator, the mechanism for adding jitter, the transmitter, and the clock and data recovery mechanism are also disposed on the single semiconductor substrate.

36. A built-in self-test (BIST) apparatus for jitter tolerance for use on a serial transceiver, the serial transceiver including one or more transmitters and one or more receivers disposed on a single semiconductor substrate, the BIST apparatus comprising:
means for generating a serialization clock, the means for generating being disposed on the single semiconductor substrate;
means for adding one or more known and controlled amounts of jitter to the serialization clock, the means for adding being disposed on the single semiconductor substrate;
means for using the serialization clock with added jitter to transmit a known sequence of test signals, the means for using being disposed on the single semiconductor substrate;
means for recovering the test signals, the means for recovering being disposed on the single semiconductor substrate; and
means for verifying that the recovered test signals match the known sequence of test signals, the means for verifying being disposed on the single semiconductor substrate.

37. A built-in self-test (BIST) apparatus for jitter tolerance for use on a serial receiver, the serial receiver being disposed on a single semiconductor substrate, the BIST apparatus comprising:
a sequential test signal generator to apply a known sequence of test signals that contain negligible jitter relative to a local reference clock to the receiver;
a clock and data recovery mechanism in the receiver to recover the test signals, the clock and data recovery mechanism being disposed on the single semiconductor substrate;
a mechanism to add one or more known and controlled amount of jitter into the clock recovery mechanism which cause the clock recovery mechanism to compensate for the added jitter, the mechanism to add jitter being disposed on the single semiconductor substrate; and
a bit stream verification mechanism used to verify that the recovered test signals match the known test signals thereby confirming that the clock and data recovery mechanism can tolerate the jitter that was added.

38. A built-in self-test (BIST) apparatus for jitter tolerance for use on a serial receiver, the serial receiver being disposed on a single semiconductor substrate, the BIST apparatus comprising:
means for applying a known sequence of test signals that contain negligible jitter relative to a local reference clock to the receiver;
means for recovering the clock and data contained in the test signals, the means for recovering being disposed on the single semiconductor substrate;
means for adding one or more known and controlled amount of jitter into the clock recovery mechanism which cause the clock recovery mechanism to compensate for the added jitter, the means for adding being disposed on the single semiconductor substrate; and
means for verifying that the recovered test signals match the known test signals thereby confirming that the clock and data recovery mechanism can tolerate the jitter that was added.

39. A built-in self-test (BIST) apparatus for jitter transfer for use on a serial transceiver, the serial transceiver including at least one transmitter and at least one receiver disposed on a semiconductor substrate, the BIST apparatus comprising:
a serialization clock generator to generate a serialization clock, the serialization clock generator being disposed on the semiconductor substrate;
a mechanism for adding one or more known and controlled amount of jitter to the serialization clock, the mechanism for adding being disposed on the semiconductor substrate;
a transmitter that uses the serialization clock with the added jitter to transmit a sequence of test signals, the transmitter being disposed on the semiconductor substrate;
a clock and data recovery mechanism in a receiver to recover the test signals, the clock and data recovery mechanism being disposed on the semiconductor substrate;
a mechanism to monitor and measure the amount of jitter present in the recovered clock signal, the mechanism to monitor and measure being disposed on a semiconductor substrate; and
a mechanism to compare the jitter present in the recovered clock with the jitter added to the serialization clock thereby testing the jitter transfer characteristic of the transceiver, the mechanism to compare being disposed on the semiconductor substrate.

40. A built-in self-test (BIST) apparatus for jitter transfer for use on a serial receiver, the serial receiver being fully contained on a single semiconductor substrate, the BIST apparatus comprising:
a signal generator to apply a sequence of test signals that contain negligible jitter relative to a local reference clock to the receiver;
a clock and data recovery mechanism in the receiver to recover the test signals, the clock and data recovery mechanism is disposed on the single semiconductor substrate;
a mechanism to add one or more known and controlled amounts of jitter into the clock recovery mechanism which cause the clock recovery mechanism to compensate for the added jitter, the mechanism to add jitter being disposed on the single semiconductor substrate;
a mechanism to monitor and measure the amount of activity in the clock recovery mechanism, the mechanism to monitor and measure being disposed on the single semiconductor substrate; and
a mechanism to compare the amount of activity in the clock recovery mechanism with the amount expected based on the jitter added thereby testing the jitter transfer characteristic of the receiver, the mechanism to compare being disposed on the single semiconductor substrate.

41. A built-in self-test (BIST) apparatus for jitter transfer for use on a serial receiver, the serial receiver being fully contained on a single semiconductor substrate, the BIST apparatus comprising:
means for applying a sequence of test signals that contain negligible jitter relative to a local reference clock to the receiver;
means for recovering clock and data contained in the test signals, the means for recovering being disposed on the single semiconductor substrate;
means for adding one or more known and controlled amounts of jitter into the clock recovery mechanism which cause the clock recovery mechanism to compensate for the added jitter, the means for adding jitter being disposed on the single semiconductor substrate;
means for monitoring and measuring the amount of activity in the clock recovery mechanism, the means for monitoring and measuring being disposed on the single semiconductor substrate; and
means for comparing the amount of activity in the clock recovery mechanism with the amount expected based on the jitter added thereby testing the jitter transfer characteristic of the receiver, the mechanism to compare being disposed on the single semiconductor substrate.

42. A built-in self-test (BIST) apparatus for a FIFO (First In First Out) circuit on a semiconductor substrate, the BIST apparatus comprising:
an on-chip clock generator capable of creating an on-chip clock signal with frequency that match the frequency of a reference clock;
a mechanism for adding known and controlled amount of phase shifts to the on-chip clock signal;
a FIFO circuit that has the reference clock and the phase shifting on-chip clock as inputs; and
a mechanism that detects when the FIFO experiences overflow and/or underflow errors;
wherein the on-chip clock generator, the mechanism for adding known and controlled amount of phase shifts to the on-chip clock signal, the FIFO, and the mechanism that detects when the FIFO experiences overflow and/or underflow errors exist on the same semiconductor substrate.

43. An apparatus for inserting known and controlled amount of jitter onto a switching signal, the apparatus comprising:
an interpolator for inserting the jitter; and
an interpolator control mechanism programmed to create the desired jitter.
